(19) United States
(12) Patent Application Publication
(10) Pub. No.: US 2011/0294075 A1
(43) Pub. Date: Dec. 1, 2011

(54) PATTERNING METHOD

(75) Inventors: Shin-Chi Chen, Tainan County (TW); Jiunn-Hsiung Liao, Tainan County (TW)

(73) Assignee: UNITED MICROELECTRONICS CORP., Hsinchu (TW)

(21) Appl. No.: 12/786,794

(22) Filed: May 25, 2010

(51) Int. Cl. G03F 7/20

(52) U.S. Cl. 430/323; 430/322

(57) ABSTRACT

A patterning method of the present invention is described as follows. A mask layer and a patterned photoresist layer are formed on a target layer in sequence, wherein an etching rate of the mask layer is different from an etching rate of the target layer. A plurality of spacers is formed on sidewalls of the patterned photoresist layer respectively, wherein an etching rate of the spacers is different from the etching rate of the mask layer. The patterned photoresist layer is removed to form an opening between any two adjacent spacers. A portion of the mask layer is removed by using the spacers as a mask so as to form a patterned mask layer. A portion of the target layer is removed by using the patterned mask layer as a mask.

### BACKGROUND OF THE INVENTION

1. Field of the Invention

The present invention relates to a semiconductor process, and more particularly, to a patterning method.

2. Description of Related Art

Along with rapid progress of semiconductor technology, the dimensions of semiconductor devices are reduced and the integrity thereof promoted continuously to further advance the operating speed and performance of integrated circuits (ICs). As the level of integration continues to increase, line width and pitch of each pattern in the integrated circuits must be reduced, so as to increase packaging density of the devices. Generally, the miniaturization of the pattern line width and the pitch in IC fabrication is mostly done by lithography having high resolution.

In the current state of lithography process, it is known that scaling down line width or peach of a pattern beyond 22 nm is rather difficult, unless a light source having an extremely shorter wavelength and a corresponding photoresist are used. Although utilizing a light source with a shorter wavelength is one way to improve the resolution, it is very costly to replace existing equipment entirely with new machines for this purpose. Conventionally, a double patterning process is developed to increase the integration degree of the devices without being limited by the resolution of the optic per se. In a double patterning process, a hard mask layer is formed on a target layer and patterned twice using different photomasks. In other words, the steps of photoresist coating, exposure, development, and hard mask etching are performed repeatedly in sequence to transfer two different groups of patterns to the hard mask layer. Thus, the patterns of the patterned hard mask layer have a smaller line width than those of the photomasks. The target layer is then patterned using the patterned hard mask layer as a mask, so as to transfer the patterns of the patterned mask layer to the target layer. In this way, a device formed from the patterned target layer has a reduced line width.

The conventional double patterning process, however, encounters problems such as intra overlay issue. Moreover, the procedure of the conventional double patterning process is complex, and therefore the cycle time and cost of the manufacturing process are increased. Hence, how to meet the purpose of miniaturizing the critical dimensions as discussed above has to be considered in the recent semiconductor technology.

### SUMMARY OF THE INVENTION

Accordingly, the present invention is directed to a patterning method, wherein not only the process is simplified but line width of the resultant patterns can be scaled down.

A patterning method of the present invention is described as follows. A mask layer and a patterned photoresist layer are formed on a target layer in sequence, wherein an etching rate of the mask layer is different from an etching rate of the target layer. A plurality of spacers is formed on sidewalls of the patterned photoresist layer respectively, wherein an etching rate of the spacers is different from the etching rate of the mask layer. The patterned photoresist layer is removed to form an opening between any two adjacent spacers. A portion of the mask layer is removed by using the spacers as a mask so as to form a patterned mask layer. A portion of the target layer is removed by using the patterned mask layer as a mask.

According to an embodiment of the present invention, the patterning method further includes forming a stop layer between the patterned photoresist layer and the mask layer. The stop layer, for example, includes a dielectric layer or a silicon-containing hard-mask bottom anti-reflection coating (SHB) layer.

According to an embodiment of the present invention, the mask layer includes a carbon-containing material layer or a photoresist layer.

According to an embodiment of the present invention, the spacers include a low-temperature dielectric material.

According to an embodiment of the present invention, the patterning method further includes removing the spacers.

According to an embodiment of the present invention, the method for forming the spacers includes forming a spacer material layer conformally on the patterned photoresist layer, and performing an anisotropic etching process to remove a portion of the spacer material layer.

A patterning method of the present invention is also described as follows. A mask layer and a patterned photoresist layer are formed on a target layer in sequence, wherein the mask layer includes a carbon-containing material layer or a photoresist layer. A plurality of spacers is formed on sidewalls of the patterned photoresist layer respectively. The patterned photoresist layer is removed to form an opening between any two adjacent spacers. A portion of the mask layer is removed by using the spacers as a mask so as to form a patterned mask layer. A portion of the target layer is removed by using the patterned mask layer as a mask.

According to an embodiment of the present invention, the patterning method further includes forming a stop layer between the patterned photoresist layer and the mask layer. When the mask layer includes the carbon-containing material layer, the stop layer includes a dielectric layer, for instance. The dielectric layer may include silicon oxide or silicon nitride. When the mask layer includes the photoresist layer, the stop layer includes a silicon-containing hard-mask bottom anti-reflection coating (SHB) layer, for instance.

According to an embodiment of the present invention, the spacers include a low-temperature dielectric material.

According to an embodiment of the present invention, the patterning method further includes removing the spacers.

According to an embodiment of the present invention, the method for forming the spacers includes forming a spacer material layer conformally on the patterned photoresist layer, and performing an anisotropic etching process to remove a portion of the spacer material layer.

As mentioned above, the patterning method in the present invention is implemented by directly forming the spacers on the sidewalls of the patterned photoresist layer. Since the spacers are utilized as the mask for transferring the patterns to the mask layer after the removal of the patterned photoresist layer, the patterned target layer defined by the patterned mask layer can have miniaturized line width or pitch. Accordingly, a semiconductor device with reduced line width can be achieved by a relatively simple process, so that cycle time and cost of the process is greatly decreased.

In order to make the aforementioned and other features and advantages of the present invention more comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1F depict, in a cross-sectional view, a patterning method according to an embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

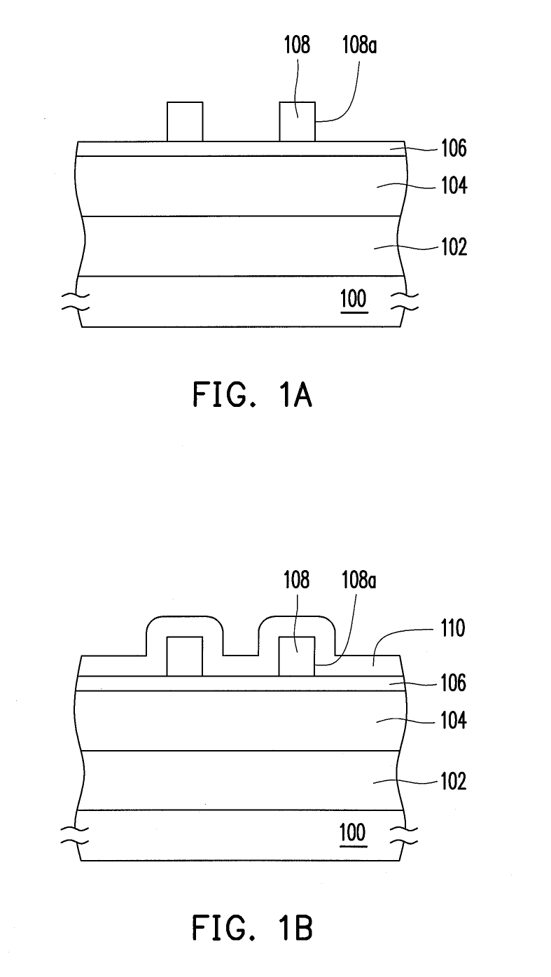

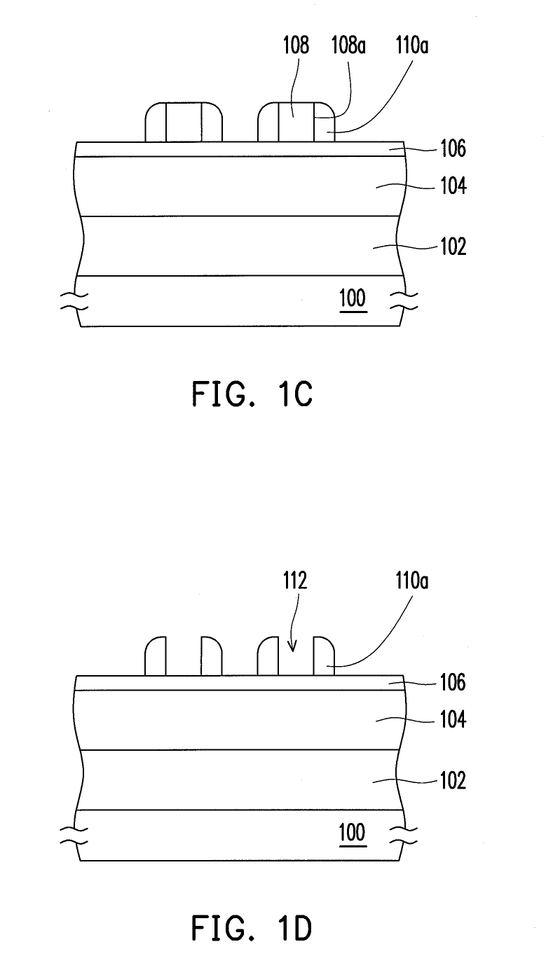

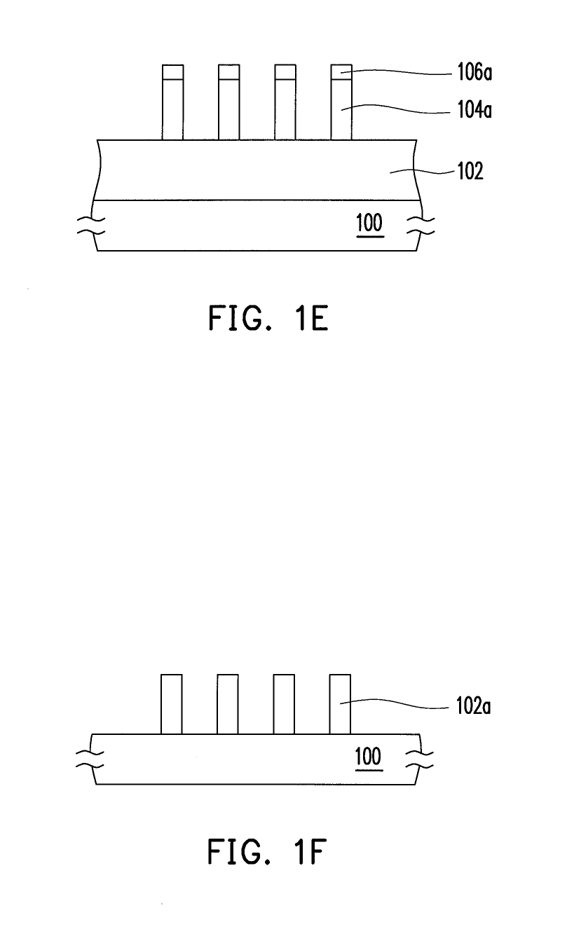

FIGS. 1A-1F depict, in a cross-sectional view, a patterning method according to an embodiment of the present invention. For illustration purposes, the following disclosure is described in terms of line patterns, which are illustrated only as an exemplary example, and should not be adopted for limiting the scope of the present invention. The arrangement or the layout of the patterns to be formed is not particularly limited by the present invention, whereas people skilled in the art should be able to embody the invention based on the illustration to obtain desirable devices with well-patterned structures.

Referring to FIG. 1A, a target layer 102 is provided, which can be formed on a substrate 100. The substrate 100 may be a semiconductor substrate, such as a silicon substrate. The target layer 102 is, for example but not limited to, a polysilicon layer, a dielectric layer, a metal layer or a conductive layer, and can be in the form of a single layer structure or a stacked multi-layered structure. The target layer 102 can be fabricated by either a physical vapor deposition (PVD) process or a chemical vapor deposition (CVD) process depending on the materials used. In an embodiment, the target layer 102 may serve as a semiconductor substrate, and therefore the substrate 100 illustrated in FIG. 1 can be omitted in this case.

Afterwards, a mask layer 104, a stop layer 106 and a patterned photoresist layer 108 are sequentially formed on the target layer 102. The mask layer 104 possesses an etching rate different from that of the target layer 102. The mask layer 104 can be a carbon-containing material layer of about 900 Å to 1500 Å or a photoresist layer of about 1500 Å to 2000 Å. In addition, other selection of the mask layer 104 can be made as long as the etching selectivity of the target layer 102 to the mask layer 104 meets the foregoing requirements. The stop layer 106 interposed between the mask layer 104 and the patterned photoresist layer 108 can be a dielectric layer or a silicon-containing hard-mask bottom anti-reflection coating (SHB) layer, which may be able to function as an etching stop layer or protection layer in later process steps. In an embodiment, when the mask layer 104 is the carbon-containing material layer, the stop layer 106 can be the dielectric layer made of silicon oxide or silicon nitride. In another embodiment, when the mask layer 104 is the photoresist layer, the stop layer 106 can be the silicon-containing hard-mask bottom anti-reflection coating (SHB) layer. The patterned photoresist layer 108, for example, has a plurality of strip-shaped structures, each of which has sidewalls 108a at respective sides. The stop layer 106 has a thickness within a range of about 200 Å to 1000 Å, while the patterned photoresist layer 108 has a thickness of about 800 Å, for example.

Referring to FIG. 1B, a spacer material layer 110 is formed on the patterned photoresist layer 108, and conformably covers the patterned photoresist layer 108 and the stop layer 106. The spacer material layer 110, the patterned photoresist layer 108 and the mask layer 104 each have different etching rates. In an embodiment, the spacer material layer 110 is made of a low-temperature dielectric material, such as silicon oxide or silicon nitride which may be fabricated by an atomic layer deposition (ALD) process under a process temperature lower than 100° C. Accordingly, the spacer material layer 110 directly formed on the patterned photoresist layer 108 scarcely impacts on the patterned photoresist layer 108 owing to the low-temperature fabrication process, and photoresist collapse or deformation can thus be prevented.

Referring to FIG. 1C, an anisotropic etching process is performed to remove a portion of the spacer material layer 110, so as to form spacers 110a on the sidewalls 108a of the patterned photoresist layer 108. In other words, each sidewall 108a of the patterned photoresist layer 108 has a spacer 110a correspondingly formed thereon, and the spacers 110a directly contact the respective sidewalls 108a of the patterned photoresist layer 108. In an embodiment, line width of the spacers 110a can be less than that of the patterned photoresist layer 108. The line width of the spacers 110a and the pitch between two adjacent spacers can be determined by the deposited thickness of the spacer material layer 110. Since the spacers 110a are utilized as a mask for defining the patterns of the mask layer 104 that may be further transferred to the target layer 102 in subsequent steps, the desirable line width or pitch of a resultant patterned target layer can be effectively miniaturized by well adjusting the deposited thickness of the spacer material layer 110.

Referring to FIG. 1D, the patterned photoresist layer 108 is then removed, so that the spacers 110 remains on the stop layer 106, and an opening 112 is formed between any two adjacent spacers 110. That is, a portion of the surface of the stop layer 106 is exposed by the openings 112. The patterned photoresist layer 108 can be removed by performing a wet stripping process or a plasma ashing process. Owing to the existence of the intervening stop layer 106, the mask layer 104 can be free from damage during the photoresist stripping process.

Referring to FIG. 1E, a portion of the stop layer 106 and a portion of the mask layer 104 are sequentially removed by using the remaining spacers 110 as a mask, so as to form a patterned stop layer 106a and a patterned mask layer 104a. The formation of the patterned stop layer 106a and the patterned mask layer 104a can be implemented by performing a dry etching process.

Referring to FIG. 1F, the spacers 110 are removed. A portion of the target layer 102 is then removed by using the patterned stop layer 106a and the patterned mask layer 104a as a mask, so as to form a patterned target layer 102a. The removal of a portion of the target layer 102 can be implemented by performing a dry etching process. After the formation of the patterned target layer 102a, the patterned stop layer 106a and the patterned mask layer 104a can be removed. Since the patterned mask layer 104a defined by the spacers 110a is utilized as the mask for patterning the target layer 102, the patterns of the resultant patterned target layer 102a can have shrunk line width or narrow pitch.

It should be noted that the patterned target layer 102a may be substantially arranged in strips. Another patterning process can be further performed to the strip-shaped patterned target layer 102a, so as to cut the strip-shaped structures into a plurality of block-shaped structures (not shown). The method for forming the said block-shaped structures, e.g. by other lithography and etching processes, is well appreciated by persons skilled in the art, and thus, the detailed descriptions thereof are not described herein. In addition, after the advantageous patterning method illustrated above, a series of logic process can be conducted to complete fabrication of demanded semiconductor devices.

In view of the above, the patterning method according to an embodiment of the present invention includes a step of directly forming the spacers on the sidewalls of the patterned photoresist layer. After the patterned photoresist layer is removed, the remaining spacers are utilized as the mask for defining the patterned mask layer, of which the patterns are then transferred to the target layer. Accordingly, the line width or pitch of the patterned target layer can be effectively miniaturized by controlling the thickness of the spacer material layer deposited on the patterned photoresist layer. It should also be noted that the present invention overcomes the limitations encountered by lithography in this generation to fabricate patterns with smaller line width or pitch through the current lithographic techniques. That is to say, the patterning method of the present invention can achieve the pattern line width of the next generation lithography using the current lithographic techniques and existing machines.

In addition, the spacers are formed on the sidewalls of the patterned photoresist layer, rather than sidewalls of another hard mask layer defined by the patterned photoresist layer. The patterning method in the present invention relies on merely a single mask layer through the spacers formed on the sidewalls of the patterned photoresist layer, so as to easily be incorporated into the current process. Thus, the patterning method in the present invention is simplified owing to the omission of another hard mask layer, thereby facilitating the shortening of cycle time and the reduction of process cost.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A patterning method, comprising:
forming a mask layer and a patterned photoresist layer on a target layer in sequence, wherein an etching rate of the mask layer is different from an etching rate of the target layer;
forming a plurality of spacers on sidewalls of the patterned photoresist layer respectively, wherein an etching rate of the spacers is different from the etching rate of the mask layer;
removing the patterned photoresist layer to form an opening between any two adjacent spacers;
removing a portion of the mask layer by using the spacers as a mask so as to form a patterned mask layer; and
removing a portion of the target layer by using the patterned mask layer as a mask.

2. The patterning method according to claim 1, further comprising forming a stop layer between the patterned photoresist layer and the mask layer.

3. The patterning method according to claim 2, wherein the stop layer comprises a dielectric layer or a silicon-containing hard-mask bottom anti-reflection coating (SHB) layer.

4. The patterning method according to claim 1, wherein the mask layer comprises a carbon-containing material layer or a photoresist layer.

5. The patterning method according to claim 1, wherein the spacers comprise a low-temperature dielectric material.

6. The patterning method according to claim 1, further comprising removing the spacers.

7. The patterning method according to claim 1, wherein the method for forming the spacers comprises:
forming a spacer material layer conformally on the patterned photoresist layer; and
performing an anisotropic etching process to remove a portion of the spacer material layer.

8. A patterning method, comprising:
forming a mask layer and a patterned photoresist layer on a target layer in sequence, wherein the mask layer comprises a carbon-containing material layer or a photoresist layer;
forming a plurality of spacers on sidewalls of the patterned photoresist layer respectively;
removing the patterned photoresist layer to form an opening between any two adjacent spacers;
removing a portion of the mask layer by using the spacers as a mask so as to form a patterned mask layer; and
removing a portion of the target layer by using the patterned mask layer as a mask.

9. The patterning method according to claim 8, further comprising forming a stop layer between the patterned photoresist layer and the mask layer.

10. The patterning method according to claim 9, wherein the stop layer comprises a dielectric layer when the mask layer comprises the carbon-containing material layer.

11. The patterning method according to claim 10, wherein the dielectric layer comprises silicon oxide or silicon nitride.

12. The patterning method according to claim 9, wherein the stop layer comprises a silicon-containing hard-mask bottom anti-reflection coating (SHB) layer when the mask layer comprises the photoresist layer.

13. The patterning method according to claim 8, wherein the spacers comprise a low-temperature dielectric material.

14. The patterning method according to claim 8, further comprising removing the spacers.

15. The patterning method according to claim 8, wherein the method for forming the spacers comprises:
forming a spacer material layer conformally on the patterned photoresist layer; and
performing an anisotropic etching process to remove a portion of the spacer material layer.
